(19) United States
(12) Patent Application Publication
(10) Pub. No.: US 2010/0237355 A1
(43) Pub. Date: Sep. 23, 2010

(54) THIN FILM TRANSISTOR, METHOD FOR MANUFACTURING THIN FILM TRANSISTOR, AND DISPLAY DEVICE

(76) Inventors: Masao Moriguchi, Osaka (JP); Yuichi Saito, Osaka (JP); Hidayat Kisdarjono, Camas, WA (US)

Correspondence Address: NIXON & VANDERHYE, PC, 901 NORTH GLEBE ROAD, 11TH FLOOR, ARLINGTON, VA, 22203, US

(21) Appl. No.: 12/743,059

(22) PCT Filed: Nov. 10, 2008
(86) PCT No.: PCT/JP2008/003245

§ 371 Date: May 14, 2010

Related U.S. Application Data
(60) Provisional application No. 60/996,394, filed on Nov. 15, 2007.

(51) Int. Cl. H01L 29/786; H01L 33/16; H01L 21/336

(52) U.S. Cl. 257/72; 257/66; 438/158; 257/E29.294; 257/E33.053; 257/E21.414

(57) ABSTRACT

A thin film transistor with a large on-current and a reduced off-current is provided with high fabrication efficiency.

A thin film transistor of the present invention includes a gate electrode; and a microcrystalline silicon layer containing a microcrystalline silicon, the microcrystalline silicon layer having an upper surface and a lower surface which are parallel to a substrate surface and an end surface which extends between the upper surface and the lower surface; first and second contact layers containing impurities which are provided so as to be in contact with the microcrystalline silicon layer; a source electrode which is in contact with the first contact layer; and a drain electrode which is in contact with the second contact layer, wherein at least one of the first and second contact layers is in contact with the microcrystalline silicon layer only at the end surface without being in contact with any of the upper surface and the lower surface.

### TECHNICAL FIELD

The present invention relates to a thin film transistor (TFT) and specifically to a thin film transistor for use in display devices, such as liquid crystal display devices, organic EL display devices, etc.

### BACKGROUND ART

Conventionally, as a TFT (Thin Film Transistor) for an active matrix substrate for use in display devices, such as liquid crystal display devices, a TFT in which a semiconductor layer includes amorphous silicon (amorphous silicon TFT) and a TFT in which a semiconductor layer includes low temperature crystallized silicon (low temperature crystallized silicon TFT) have been used.

The low temperature crystallized silicon TFT exhibits high mobility of electrons and holes in a semiconductor layer and hence has a large on-current, and therefore has an advantage that the pixel capacitance of a liquid crystal display device, or the like, can be charged within a short switching interval. Also, it has another advantage that a part or the entire of peripheral circuits, such as a driver, etc., can be built within the extent of the active matrix substrate.

However, the fabrication process of the low temperature crystallized silicon TFT includes complicated steps, such as a laser crystallization step, an annealing step, and an ion doping step. Therefore, the fabrication cost per unit substrate area increases. Because of this disadvantage, the low temperature crystallized silicon TFT is generally used in applications of middle-size and small-size liquid crystal panels in many cases.

On the other hand, the amorphous silicon TFT is suitable to an active matrix substrate of a device which requires a large display surface because formation of an amorphous silicon film is relatively easy. Therefore, the amorphous silicon TFT has been used in many of active matrix substrates of liquid crystal television displays. An example of the amorphous silicon TFT is described in Patent Document 1.

In recent years, higher display quality and lower power consumption, as well as larger display sizes, have been demanded of liquid crystal display devices, such as liquid crystal television displays. In view of these demands, improvements have been made in various parts of the liquid crystal display devices. Notwithstanding the improvements, the amorphous silicon TFT has a problem that the mobility is very low, for example, about 0.5 cm²/Vs, so that the on-current is small. However, it is difficult to increase the mobility in the amorphous silicon TFT, and thus, improving the performance of the liquid crystal display devices by making improvements to the amorphous silicon TFT has a limit.

With the view of improving the performance of TFTs, uses of new materials for a semiconductor layer other than the amorphous silicon and the low temperature crystallized silicon have been studied. Patent Document 2 describes, as an example of such a TFT, a TFT which has semiconductor layers including a microcrystalline silicon (μc-Si) layer. Microcrystalline silicon (or polycrystalline silicon) is a type of silicon which has a microcrystalline phase. A microcrystalline silicon film is commonly formed using the same method as that used for formation of an amorphous silicon film, for example, plasma CVD. The material gas commonly used is a silane gas diluted with a hydrogen gas. The diameter of crystal grains contained in the microcrystalline silicon is small, for example, several nanometers to several hundreds of nanometers. The microcrystalline silicon formed is, in many cases, in the form of a mixture of crystal grains and amorphous silicon.

Microcrystalline silicon is characterized in that basic crystal grains are already included in the film at the time of completion of film formation by means of a CVD apparatus, or the like, whereas formation of a low temperature crystallized silicon film includes formation of an amorphous silicon film, which is necessarily followed by a crystallization step by means of laser or heat. Therefore, an annealing step by means of laser or heat for formation of crystal grains after formation of a film can be omitted. Thus, the microcrystalline silicon TFT can be fabricated through a smaller number of steps than that required for fabrication of the low temperature crystallized silicon TFT, and can be fabricated through a generally equal number of steps at a generally equal fabrication cost to those required for the amorphous silicon TFT.

[Patent Document 1] Japanese Patent No. 3322978

[Patent Document 2] Japanese Laid-Open Patent Publication No. H6-196701

### DISCLOSURE OF INVENTION

### Problems to be Solved by the Invention

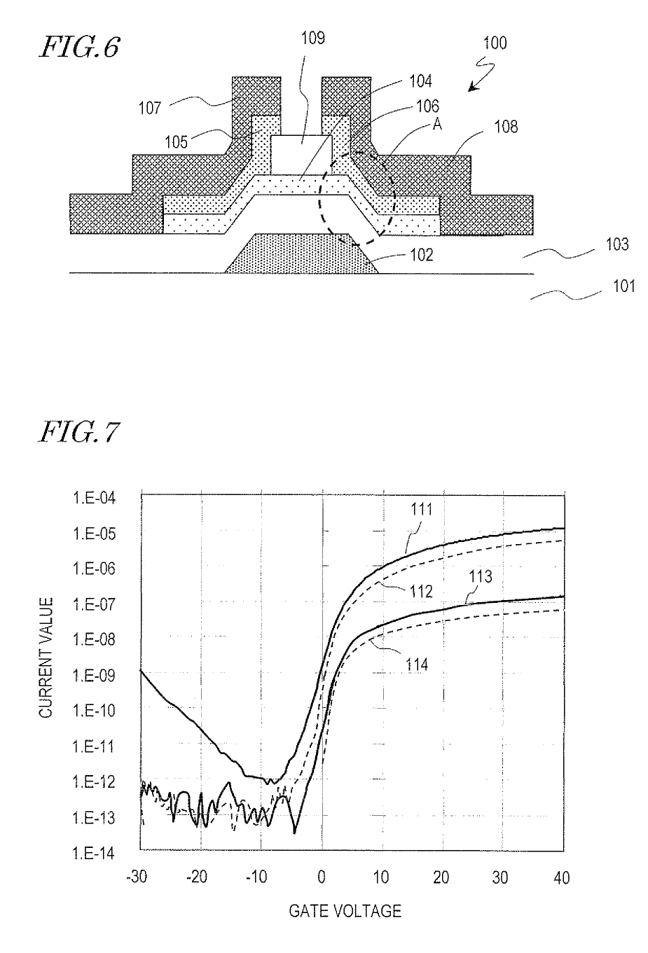

FIG. 6 is a cross-sectional view showing a reference example of a microcrystalline silicon TFT.

As shown in FIG. 6, this microcrystalline silicon TFT 100 is an inverted staggered TFT which has a bottom gate structure. The microcrystalline silicon TFT 100 includes a gate electrode 102 which is provided on a glass substrate 101, a gate insulating layer 103 which is provided over the glass substrate 101 so as to cover the gate electrode 102, a microcrystalline silicon layer 104 which is provided on the gate insulating layer 103, contact layers (doped layers) 105 and 106 which are provided on the microcrystalline silicon layer 104, a source electrode 107 and a drain electrode 108 which are provided over the contact layers 105 and 106, respectively, and a channel protecting layer 109.

The contact layers 105 and 106 are n⁺ type silicon layers made of a material prepared by doping silicon with impurities. These layers are sometimes referred to as impurity silicon layers. The microcrystalline silicon TFT 100 having such a structure is capable of achieving a high mobility of 1 to 3 cm²/Vs because the semiconductor layer includes crystal grains, and is therefore capable of achieving a large on-current as compared with conventional amorphous silicon TFTs.

However, the inventor of the present application examined the characteristics of the microcrystalline silicon TFT 100 and found that the microcrystalline silicon TFT 100 has problems described below.

when the microcrystalline silicon TFT 100 is off, i.e., when a negative voltage is applied to the gate electrode 102 while a positive voltage is applied to the drain electrode 108, the density of electric lines of force is very high in a region between the gate electrode 102 and the drain electrode 108 (region A in FIG. 6). In this case, a problem that a greatly-increased off-current flows as the negative voltage applied to the gate electrode 102 decreases, a so-called off-current rising, occurs because microcrystalline silicon has a narrower band gap than that of amorphous silicon (for example, microcrystalline silicon band gap=1.1 eV whereas amorphous silicon band gap=1.7 eV) and hence has high conductivity.

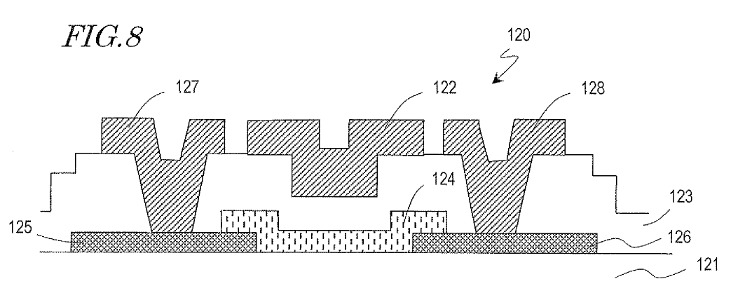

FIG. 7 shows a graph in which the on-currents and off-currents of the microcrystalline silicon TFT 100 and the amorphous silicon TFT are compared. In the graph, solid line 111 represents the on-current and off-current characteristics (also simply referred to as “current characteristic”) of the microcrystalline silicon TFT 100 with the drain voltage at 10 V, broken line 112 represents the current characteristic of the amorphous silicon TFT with the drain voltage at 10 V, solid line 113 represents the current characteristic of the microcrystalline silicon TFT 100 with the drain voltage at 0.1 V, and broken line 114 represents the current characteristic of the amorphous silicon TFT with the drain voltage at 0.1 V.

As seen from FIG. 7, the value of the on-current (the current value reached while the gate voltage is in the positive range) is larger in the microcrystalline silicon TFT 100 irrespective of whether the drain voltage is 10 V or 0.1 V. However, part of the line 111 in the negative gate voltage range shows that the microcrystalline silicon TFT 100 has a problem that the value of the off-current is very high (off-current rising).

Since, in general, the crystalline silicon includes a large number of defect levels, there is a problem that the off-current of the microcrystalline silicon TFT 100 is higher than that of the amorphous silicon TFT even when a small negative voltage is applied to the gate electrode 102 (even when the gate voltage is a negative value near zero).

Such a problem can also occur in a microcrystalline silicon TFT which has a top gate structure.

FIG. 8 is a cross-sectional view showing a reference example of a microcrystalline silicon TFT which has a top gate structure. This microcrystalline silicon TFT 120 includes contact layers 125 and 126 which are provided on a glass substrate 121, a microcrystalline silicon layer 124 which is provided on the glass substrate 121 so as to partially extend over the contact layers 125 and 126, a gate insulating layer 123, and a gate electrode 122, a source electrode 127 and a drain electrode 128 which are provided on the gate insulating layer 123. The source electrode 127 and the drain electrode 128 are in contact with the contact layer 125 and the contact layer 126, respectively, via contact holes formed in the gate insulating layer 123.

During formation, the microcrystalline silicon grows in the film thickness direction. Therefore, employing the microcrystalline silicon TFT 120 which has the above-described top gate structure enables using a high crystallinity region of the microcrystalline silicon layer 124 as a channel. Thus, the mobility can be further improved as compared with the microcrystalline silicon TFT which has the bottom gate structure. However, the microcrystalline silicon TFT 120 which has the top gate structure also has a problem of high off-current for the reasons set forth above as in the microcrystalline silicon TFT which has the bottom gate structure.

The present invention was conceived in view of the above problems. The objects of the present invention include providing a thin film transistor with a small leakage current in which the on-current easily flows while the off-current rising is decreased, and providing such a thin film transistor with high fabrication efficiency.

### Means for Solving the Problems

A thin film transistor of the present invention is a thin film transistor which has a semiconductor layer containing a microcrystalline silicon. The thin film transistor includes: a gate electrode; a microcrystalline silicon layer containing a microcrystalline silicon, the microcrystalline silicon layer having an upper surface and a lower surface which are parallel to a substrate surface and an end surface which extends between the upper surface and the lower surface; first and second contact layers containing impurities; a source electrode which is in contact with the first contact layer; and a drain electrode which is in contact with the second contact layer, wherein at least one of the first and second contact layers is in contact with the microcrystalline silicon layer only at the end surface without being in contact with any of the upper surface and the lower surface.

In one embodiment, at least part of the first and second contact layers extends over the microcrystalline silicon layer when seen in a direction perpendicular to the substrate surface.

In one embodiment, part of the source electrode extends over the first contact layer, or part of the drain electrode extends over the second contact layer, when seen in a direction perpendicular to the substrate surface.

In one embodiment, the thin film transistor is a bottom gate type thin film transistor, the first contact layer and a gate insulation layer are provided between the source electrode and the gate electrode, and the second contact layer and a gate insulation layer are provided between the drain electrode and the gate electrode.

In one embodiment, part of the microcrystalline silicon layer extends over the first contact layer or the second contact layer when seen in a direction perpendicular to the substrate surface.

In one embodiment, the thin film transistor is a top gate type thin film transistor, and the part of the microcrystalline silicon layer extends over the first contact layer or the second contact layer with an insulating layer interposed therebetween.

In one embodiment, the microcrystalline silicon layer includes a columnar crystal grown vertically to the substrate surface.

in one embodiment, a cross section of the columnar crystal which is parallel to the substrate surface has a diameter not less than 5 nm and not more than 30 nm.

In one embodiment, a crystallization rate of the microcrystalline silicon layer is 70% or more.

In one embodiment, the microcrystalline silicon layer includes a void.

In one embodiment, an infrared absorption spectrum of the microcrystalline silicon layer has a peak in a wave number range of not less than 2050 cm⁻¹ and not more than 2150 cm ⁻¹.

In one embodiment, each of the first and second contact layers includes an amorphous silicon layer which contains impurities and a microcrystalline silicon layer which contains impurities.

A display device of the present invention is a display device which includes the above-described thin film transistor.

A thin film transistor fabrication method of the present invention is a method for fabricating a thin film transistor which has a semiconductor layer containing a microcrystalline silicon. The method includes the steps of: forming a gate electrode; forming a microcrystalline silicon layer which contains a microcrystalline silicon; forming first and second contact layers which contain impurities; and forming a source electrode and a drain electrode so as to be in contact with the first and second contact layers, respectively, wherein the microcrystalline silicon layer has an upper surface and a lower surface which are parallel to a substrate surface and an end surface which extends between the upper surface and the lower surface, and at least one of the first and second contact layers and the microcrystalline silicon are formed so as to be in contact with each other only at the end surface of the microcrystalline silicon layer without having a contact at any of the upper surface and the lower surface.

in one embodiment, the step of forming the first and second contact layers includes forming a layer of a silicon which contains impurities, and reshaping the layer of the silicon which contains the impurities to form the first and second contact layers.

In one embodiment, the thin film transistor is a bottom gate type thin film transistor, the step of forming the gate electrode and the step of forming the microcrystalline silicon layer is performed before the step of forming the first and second contact layers, and the first and second contact layers, the source electrode, and the drain electrode are formed by reshaping with the use of a single pattern.

in one embodiment, the thin film transistor is a top gate type thin film transistor, the step of forming the microcrystalline silicon layer, the step of forming the gate electrode, the step of forming the source electrode and the drain electrode is performed after the step of forming the first and second contact layers, and the step of forming the first and second contact layers includes forming a silicon film which contains impurities, forming an insulating film on the silicon film, and reshaping the silicon film and the insulating film with the use of a single pattern.

In one embodiment, the method further includes, before forming the layer of the silicon which contains the impurities, doping the microcrystalline silicon layer with impurities using a gas which contains phosphine (PH₃).

In one embodiment, the method further includes, after forming the layer of the silicon which contains the impurities, thermally treating the layer of the silicon which contains the impurities at a temperature not less than 250° C. and not more than 320° C.

In one embodiment, the step of forming the microcrystalline silicon layer includes forming a microcrystalline silicon film by high-density plasma CVD, and reshaping the microcrystalline silicon film to form the microcrystalline silicon layer.

In one embodiment, the step of forming the microcrystalline silicon film includes forming the microcrystalline silicon layer at a pressure not less than 0.133 Pa (pascal) and not more than 13.3 Pa.

In one embodiment, the microcrystalline silicon film is formed on a silicon nitride film after a hydrogen plasma treatment is performed on the silicon nitride film.

Note that the invention of the present application also includes a circuit substrate which includes a thin film transistor of the present invention. The invention of the present application also includes a circuit substrate which includes a thin film transistor fabricated using a fabrication method of the present invention. The invention of the present application also includes a display device which has such a circuit substrate, such as liquid crystal display devices, organic EL (electroluminescence) display devices, etc., and an imaging device which has the circuit substrate.

### Effects of The Invention

A thin film transistor of the present invention includes microcrystalline silicon in a semiconductor layer and therefore exhibits an excellent on-current characteristic. Further, the contact layers and the microcrystalline silicon layer are joined together only at the end surfaces of the microcrystalline silicon layer, and thus, the off-current rising is prevented so that the leakage current decreases.

Fabrication of the thin film transistor of the present invention does not include an impurity introduction process for ion implantation after formation of the contact layers, such as that described in Patent Document 1. Therefore, a thin film transistor which is suitable to large-size display devices, etc., can be fabricated with high fabrication efficiency and low fabrication cost.

In the thin film transistor of the present invention, the microcrystalline silicon layer includes columnar crystals which are grown vertically to the substrate surface, and therefore, the mobility in the active layer is high, so that a large on-current can be obtained. Further, by limiting the diameter of the columnar crystal in a plane parallel to the substrate surface to a length not less than 5 nm and not more than 30 nm, the minimum value of the off-current is decreased so that the leakage current can be decreased.

Further, by limiting the crystallization rate of the microcrystalline silicon layer to 70% or more, the high mobility can be achieved in the active layer. Further, the microcrystalline silicon layer may include voids. In this case, an excellent state of electric junction can be achieved even in a thin film transistor which has a small junction surface between the contact layers and the microcrystalline silicon layer.

According to the present invention, a thin film transistor which exhibits excellent on-current and off-current characteristics and which is suitable to large-size display devices can be provided with high fabrication efficiency.

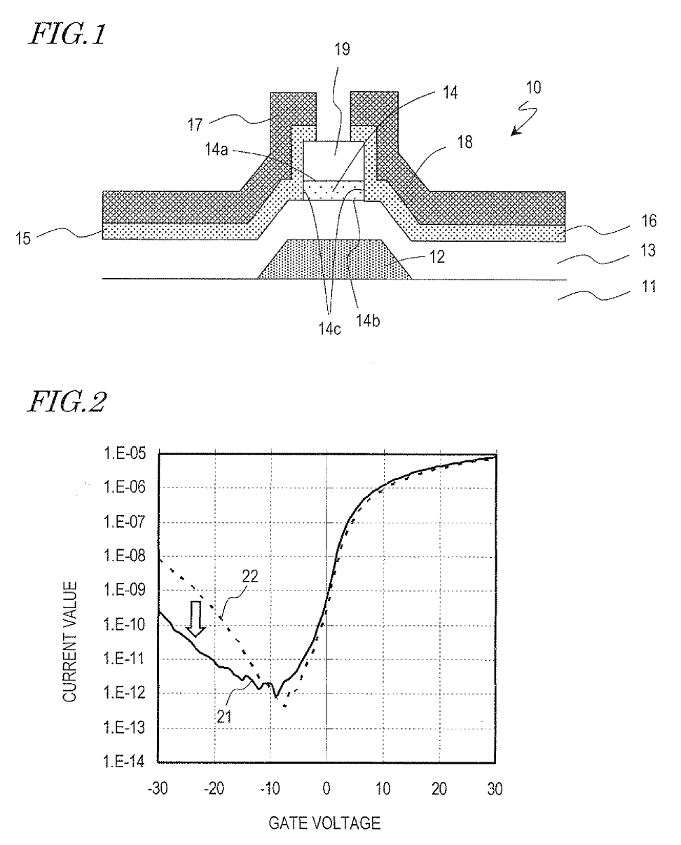

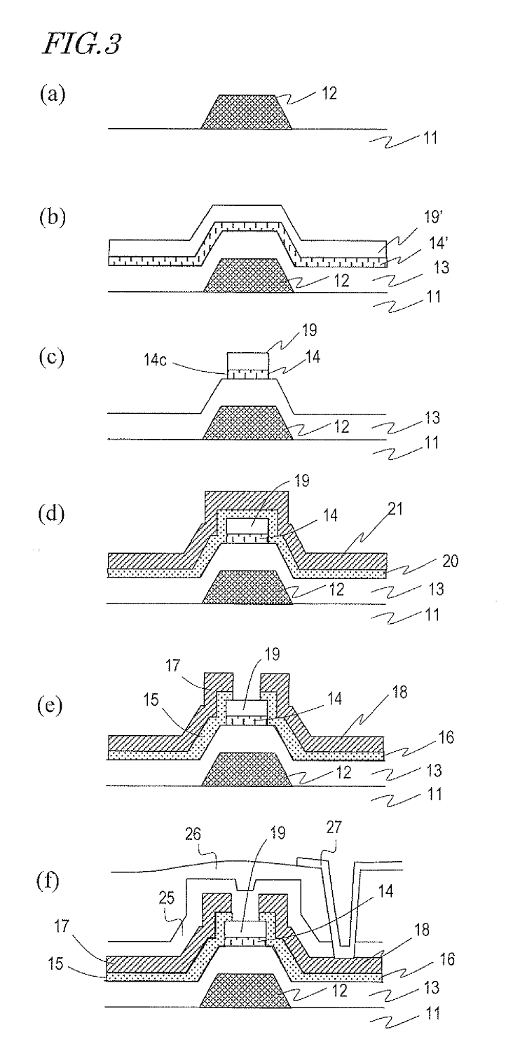

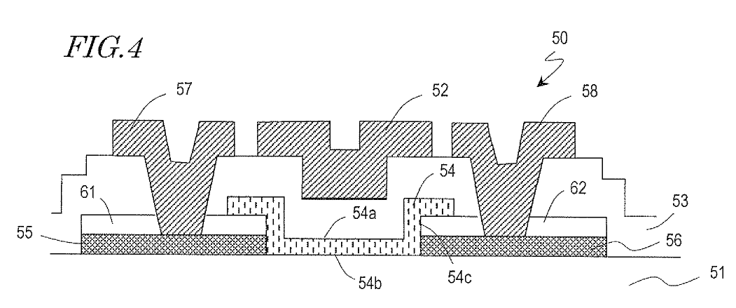

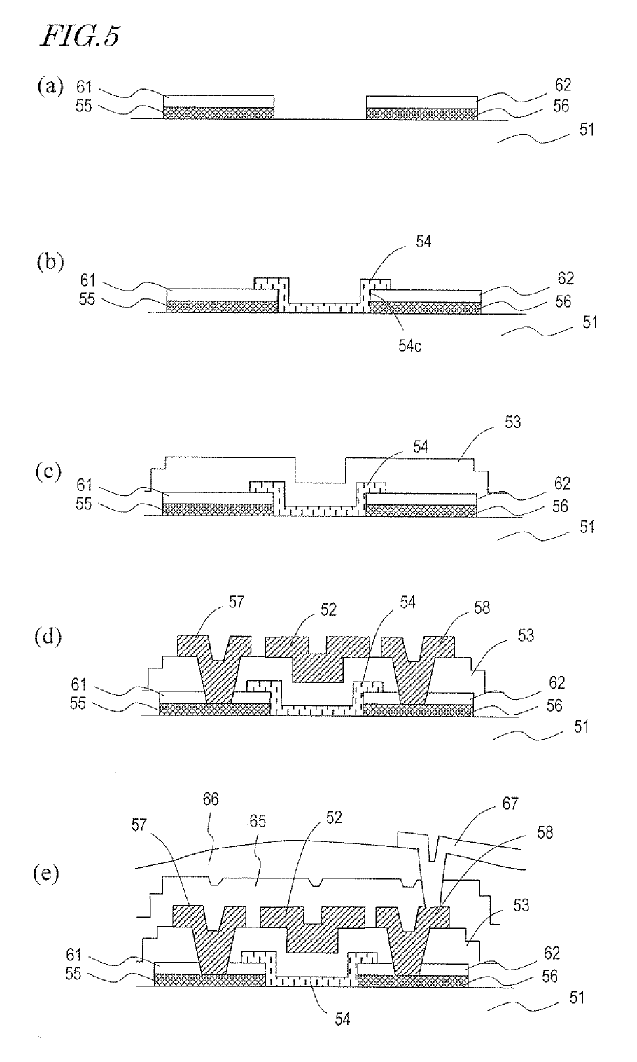

### BRIEF DESCRIPTION OF DRAWINGS

[FIG. 1] A cross-sectional view schematically showing the structure of a thin film transistor of embodiment 1 of the present invention.

[FIG. 2] A graph showing the comparison of the current characteristic between the thin film transistor of embodiment 1 and a microcrystalline silicon TFT shown in FIG. 6.

[FIG. 3] (a) to (f) are cross-sectional views which show a method for fabricating the thin film transistor of embodiment 1.

[FIG. 4] A cross-sectional view schematically showing the structure of a thin film transistor of embodiment 2 of the present invention.

[FIG. 5] (a) to (e) are cross-sectional views which show a method for fabricating the thin film transistor of embodiment 2.

[FIG. 6] A cross-sectional view showing an example of a bottom gate type microcrystalline silicon TFT.

[FIG. 7] A graph showing the comparison of the current characteristic between a microcrystalline silicon TFT and an amorphous silicon TFT.

[FIG. 8] A cross-sectional view showing an example of a top gate type microcrystalline silicon TFT.

### DESCRIPTION OF THE REFERENCE NUMERALS

10, 50 thin film transistor

11, 51 glass substrate

12, 52 gate electrode

13, 53 gate insulating layer

14, 54 microcrystalline silicon layer

14a upper surface

14b lower surface

14c end surface

14′ microcrystalline silicon film

15, 16, 55, 56 contact layer

17, 57 source electrode

18, 58 drain electrode

19 channel protecting layer

19′ silicon nitride film

20 n⁺ silicon film

21 molybdenum film

25, 65 silicon nitride layer

26, 66 planarization layer

27, 67 transparent electrode

61, 62 silicon oxide layer

100, 120 microcrystalline silicon TFT

101, 121 glass substrate

102, 122 gate electrode

103, 123 gate insulating layer

104, 124 microcrystalline silicon layer

105, 106, 125, 126 contact layer

107, 127 source electrode

108, 128 drain electrode

109 channel protecting layer

### BEST MODE FOR CARRYING OUT THE INVENTION

Hereinafter, a thin film transistor of an embodiment of the present invention is described with reference to the drawings.

### Embodiment 1

FIG. 1 is a cross-sectional view which schematically shows a structure of a thin film transistor 10 of embodiment 1 of the present invention. As shown in FIG. 1, the thin film transistor 10 is an inverted staggered TFT which has a bottom gate structure. The thin film transistor 10 includes a gate electrode 12 which is provided on a glass substrate 11, a gate insulating layer 13 which is provided over the glass substrate 11 so as to cover the gate electrode 12, a microcrystalline silicon layer 14 which is an active layer provided on the gate insulating layer 13, a contact layer 15 (first contact layer) and a contact layer 16 (second contact layer) which are provided on the microcrystalline silicon layer 14, a source electrode 17 and a drain electrode 18 which are provided over the contact layers 15 and 16, respectively, and a channel protecting layer 19.

The microcrystalline silicon layer 14 has an upper surface 14a and a lower surface 14b which are substantially parallel to a substrate surface (a surface of the glass substrate 11 or a substrate surface of the thin film transistor 10), and end surfaces (side surfaces) 14c which extend between the upper surface 14a and the lower surface 14b. The contact layer 15 and the contact layer 16 are in contact with the microcrystalline silicon layer 14 only at the end surfaces 14c without being in contact with any of the upper surface 14a and the lower surface 14b.

The contact layers 15 and 16 are made of impurity-doped n⁺ type silicon (n⁺-Si). When seen in a direction perpendicular the substrate surface, part of each of the contact layers 15 and 16 extends over the microcrystalline silicon layer 14 with the channel protecting layer 19 interposed therebetween. Also, when seen in a direction perpendicular the substrate surface, part of the source electrode 17 extends over the microcrystalline silicon layer 14 with the channel protecting layer 19 and the contact layer 15 interposed therebetween, and part of the drain electrode 18 extends over the microcrystalline silicon layer 14 with the channel protecting layer 19 and the contact layer 16 interposed therebetween.

The microcrystalline silicon layer 14 is composed of amorphous silicon and columnar crystals which are grown vertically to the substrate surface. A cross section of the columnar crystal which is parallel to the substrate surface preferably has a diameter not less than 5 nm and not more than 30 nm. The microcrystalline silicon layer 14 has a crystallization rate of 70% or more and includes voids. The microcrystalline silicon layer 14 is made of a material that is characterized by an infrared absorption spectrum which has a peak near the wave number of 2100 cm⁻¹ or in a wave number range of not less than 2050 cm⁻¹ and not more than 2150 cm⁻¹.

The thin film transistor 10 has a so-called coplanar structure, in which the contact layers 15 and 16 are joined to the microcrystalline silicon layer 14 only at the end surfaces 14c of the microcrystalline silicon layer 14. In general, in fabrication of a thin film transistor which has a coplanar structure, formation of a contact layer is followed by ion implantation which is accomplished by means of an impurity introduction process as described in Patent Document 1. Therefore, in the thin film transistor of Patent Document 1, when seen in a direction perpendicular the substrate surface, no part of the contact layer extends over the semiconductor layer, and no part of the source electrode and the drain electrode extends over the contact layer.

However, the impurity introduction process has a small throughput and therefore requires a relatively long processing time. Also, increasing the size of a process apparatus is difficult. Thus, the impurity introduction process is not suitable to a thin film transistor for use in display devices of which larger display surfaces and lower prices have been demanded.

On the other hand, fabrication of the thin film transistor 10 of this embodiment does not require an additional impurity introduction process because the contact layers 15 and 16 are obtained by directly forming a silicon film which contains impurities. Therefore, when seen in a direction perpendicular the substrate surface, part of the contact layers 15 and 16 can be formed so as to extend over the microcrystalline silicon layer 14, and part of the source electrode 17 and the drain electrode 18 can be formed so as to extend over the microcrystalline silicon layer 14 with the channel protecting layer and the contact layer interposed therebetween.

Since the impurity introduction process is thus not necessary, the thin film transistor 10 of embodiment 1 is of high fabrication efficiency and is suitable to, for example, a device which has a large display surface, such as large-size liquid crystal display devices.

Large part of the current flowing between the source electrode 17 and the drain electrode 18 passes through the microcrystalline silicon layer 14. Therefore, the mobility in the thin film transistor 10 is higher than that in an amorphous silicon TFT. In the thin film transistor 10, the off-current rising is prevented, so that the leakage current is also prevented, whereas the microcrystalline silicon TFT 100 shown in FIG. 6 has a problem that an off-current rising occurs as described above and a large leakage current flows.

FIG. 2 shows a graph in which the current characteristic is compared between the thin film transistor 10 of embodiment 1 and the microcrystalline silicon TFT 100 shown in FIG. 6 in the circumstance where the drain voltage is at 10 V. In the graph, solid line 21 represents the current characteristic of the thin film transistor 10, and broken line 22 represents the current characteristic of the microcrystalline silicon TFT 100. As seen from FIG. 2, in the thin film transistor 10, the value of the off-current in the off-region (herein, a region where gate voltage Vg is −15 V or less) is far smaller than that in the microcrystalline silicon TFT 100. This is for the reasons discussed below.

When the thin film transistor 10 is off, i.e., when a negative voltage is applied to the gate electrode 12 while a positive voltage is applied to the drain electrode 18, electric lines of force are generated at a high density in a region between the gate electrode 12 and the drain electrode 18. However, in the microcrystalline silicon TFT 100 of FIG. 6, the overlapping area of the microcrystalline silicon layer 104 and the contact layer 106 in this region is large (the length of the contact portion of these layers in the cross section shown in FIG. 6 is from 500 nm to 5000 nm), so that a large off-current flows when the gate voltage is lower than −15 V (occurrence of an off-current rising).

On the other hand, in the thin film transistor 10 of embodiment 1, the overlapping area of the microcrystalline silicon layer 14 and the contact layer 16 is small (the length of the contact portion of these layers in the cross section shown in FIG. 1 is about 100 nm), so that the off-current can be limited to a small current. Note that the present inventor experimentally confirmed that the off-current in the thin film transistor 10 is smaller than that in the microcrystalline silicon TFT 100 of FIG. 6 by one or more orders of magnitude.

Employing the coplanar structure enables electrons to flow more smoothly from the source electrode 17 to the drain electrode 18 via the channel, so that a large on-current advantageously flows.

In the microcrystalline silicon TFT 100 of FIG. 6, the source electrode 107 and the drain electrode 108 extend over the microcrystalline silicon layer 104 so that the microcrystalline silicon layer 104 is readily affected by the voltage applied to the drain electrode 108. Therefore, the short channel effects and the off breakdown voltage during application of a high voltage to the drain electrode 108 are low. However, the thin film transistor 10 employs a coplanar structure and can therefore enjoy improved short channel effects and improved off breakdown voltage.

In a thin film transistor in which the active layer includes crystalline silicon, the crystalline silicon used may generally be a crystalline silicon crystallized by laser or a crystalline silicon crystallized by solid phase crystallization (SPC). Such a crystalline silicon has a low resistance value, resulting in a large off-current.

On the other hand, the microcrystalline silicon has intermediate properties between those of crystalline silicon and those of amorphous silicon. The microcrystalline silicon has a higher resistance value than the above-described crystalline silicon and can enjoy improved defective edge termination effects by means of defective edge termination with hydrogen. Therefore, the off-current can be decreased to a level which is supposed to be achieved with amorphous silicon, without an additional resistance region such as that provided in a LDD (Lightly Doped Drain) structure.

In the thin film transistor 10, each of the contact layers 15 and 16 and the microcrystalline silicon layer 14 are joined together only at the end surface 14c of the microcrystalline silicon layer 14. Therefore, the area of the junction of these layers is small as compared with the microcrystalline silicon TFTs 100 and 120 shown in FIG. 6 and FIG. 8, and thus, occurrence of the photocurrent can be prevented.

The microcrystalline silicon layer 14 of embodiment 1 includes columnar crystals grown vertically to the substrate surface. Should a cross section of the columnar crystal which is parallel to the substrate surface have a diameter greater than 30 nm, the resistance value of the microcrystalline silicon layer 14 decreases, and accordingly, the minimum value of the off-current increases. Thus, the diameter of the columnar crystal is preferably not less than 5 nm and not more than 30 nm.

Should the crystallization rate of the microcrystalline silicon layer 14 be less than 70%, the crystallinity is too low so that the mobility deteriorates. Thus, in the thin film transistor 10 of this embodiment, the crystallization rate of the microcrystalline silicon layer 14 is 70% or more.

In the thin film transistor 10 of embodiment 1, the junction surface between each of the contact layers 15 and 16 and the microcrystalline silicon layer 14 is small, and the height of the junction surface is equal to the thickness of the microcrystalline silicon layer 14. When the junction surface is so small, the state of electric junction between these layers may be expected to deteriorate. However, the microcrystalline silicon layer 14 of embodiment 1 is porous such that a number of very small voids are included in part other than the columnar crystals. Therefore, sufficient diffusion of impurities is accomplished within a short period of time in the doping process, and an excellent state of electric junction is achieved with high fabrication efficiency. Note that, by providing very small voids with the diameter not less than 5 nm and not more than 30 nm between the columnar crystals, a more excellent state of electric junction can be obtained.

The microcrystalline silicon layer 14 exhibits an infrared absorption spectrum which has a peak near the wave number of 2100 cm⁻¹. This peak preferably occurs in a range of not less than 2050 cm⁻¹ and not more than 2150 cm⁻¹.

Inclusion of many voids in the microcrystalline silicon layer 14 means that the microcrystalline silicon layer 14 includes many Si—H₂ bonds which are two-dimensional structures and many (Si—H₂)n chains. Therefore, the density of the voids is reflected in the position of the peak in the infrared absorption spectrum of the microcrystalline silicon layer 14 (or its constituent materials). This peak position can be measured by FT-IR (Fourier Transform InfraRed Spectrophotometer).

Occurrence of the peak near the wave number of 2100 cm⁻¹ as described above means that the density of the voids is optimum so that an excellent state of electric junction can be obtained. Note that one of the methods proposed for measuring the density of the voids is ellipsometry, such as spectroellipsometry.

Each of the contact layers 15 and 16 is composed of impurity-doped microcrystalline silicon (n⁺μc-Si) or amorphous silicon (n⁺a-Si) but alternatively may have a two-layer structure which consists of an amorphous silicon layer containing impurities and a microcrystalline silicon layer containing impurities. Especially, by forming the two-layer structure of an high-resistance n⁺μc-Si layer of about 20 nm thick and a low-resistance n⁺a-Si layer of about 40 nm thick overlying the high-resistance layer, the on-current value can be increased while the off-current is decreased. Note that, in this case, the sheet resistance of n⁺a-Si is preferably about 5×10⁷ to 5×10⁸ Ω/cm², and the sheet resistance of n⁺μc-Si is preferably about 5×10⁴ to 1×10⁶ Ω/cm².

For the reasons set forth above, in the thin film transistor 10 of embodiment 1, a high on-current value can be achieved while the off-current is decreased. Such an excellent current characteristic would not be obtained in thin film transistors in which the active layer includes amorphous silicon or crystalline silicon.

Note that, in this embodiment, both the contact layer 15 and the contact layer 16 are in contact with the microcrystalline silicon layer 14 only at the end surfaces 14c. However, the thin film transistor of the present invention includes another embodiment where one of the contact layer 15 and the contact layer 16 is in contact with the microcrystalline silicon layer 14 only at the end surface 14c. Although in this embodiment part of each of the contact layers 15 and 16 extends over the microcrystalline silicon layer 14 when seen in a direction perpendicular the substrate surface, the thin film transistor of the present invention includes another embodiment where part of one of the contact layers 15 and 16 extends over the microcrystalline silicon layer 14. The thin film transistor of the present invention includes still another embodiment where, when seen in a direction perpendicular the substrate surface, part of one of the source electrode 17 and the drain electrode 18 extends over the microcrystalline silicon layer 14 with the channel protecting layer and the contact layer interposed therebetween.

Also, a variety of devices which include the above-described thin film transistor, and display devices which use the above-described thin film transistor as a switching element for display, such as liquid crystal display devices, organic EL display devices, etc., may be within the scope of the present invention.

Next, a method for fabricating the thin film transistor 10 of embodiment 1 is described with reference to FIG. 3.

FIG. 3 is a cross-sectional view which illustrates a method for fabricating the thin film transistor 10. First, a TaN (tantalum nitride) layer, a Ta (tantalum) layer, and a TaN layer are formed over the glass substrate 11 by sputtering, and these three layers are photolithographically patterned to form a gate electrode 12 as shown in FIG. 3(a). The etching used herein may be dry etching with an etching gas containing oxygen. During progress of the etching, a photoresist is gradually moved away from the substrate such that the side surfaces of the gate electrode 12 are sloped about 45° relative to the substrate surface (tapering angle of about 45°).

The metals which constitute the gate electrode 12 are not limited to the above examples. For example, the gate electrode 12 may be a single layer formed of a simple metal, such as aluminum (Al), indium tin oxide (ITO), tungsten (W), copper (Cu), chromium (Cr), tantalum (Ta), molybdenum (Mo), titanium (Ti), etc., or a material composed of such a simple metal and nitrogen, oxygen, or any other metals. Alternatively, some of these materials may be used in combination to form a layered structure.

The method for forming the gate metal film may include a variety of deposition methods as well as sputtering methods. The etching employed in the formation of the gate metal film is not limited to the above examples. It may be dry etching with the use of a chlorine (Cl₂) gas, a boron trichloride (BCl₃) gas, a carbon tetrafluoride (CF₄) gas, etc., in combination.

Then, as shown in FIG. 3(b), a silicon nitride film (SiNx film) is formed as the gate insulating layer 13 to 400 nm thick by plasma CVD, and a microcrystalline silicon film 14′ and a silicon nitride film (etching stopper layer) 19′ are formed over the resultant silicon nitride film. These films are formed continuously in vacuum using a multi-chamber apparatus. The two silicon nitride films are formed by plasma CVD (Chemical Vapor Deposition) in a film formation chamber of the multi-chamber apparatus which has a parallel plate type (capacitive coupling type) electrode structure. The microcrystalline silicon film may be formed by high-density plasma CVD (ICP-CVD, surface wave CVD, or ECR-CVD).

When using capacitive coupling type plasma CVD, a film portion with the thickness of about 40 nm or less which is formed in the early part of the film formation process would be mainly composed of amorphous silicon. When using high-density plasma CVD, columnar grains of microcrystalline silicon can be formed in the microcrystalline silicon film 14 even in the early part of the film formation process. In this way, a channel layer which has high mobility can be formed.

The two silicon nitride films may be formed under the same film formation conditions as those used in a common amorphous silicon TFT fabrication process. The microcrystalline silicon film 14′ may be formed using a mixture gas containing silane (SiH₄) and hydrogen (H₂) in the ratio of 1:20 in a chamber where the pressure is 1.333 Pa (=10 mTorr) and the substrate temperature is 300° C.

The microcrystalline silicon film 14′ is preferably formed at a pressure not less than 0.1333 Pa (1 mTorr) and not more than 13.33 Pa (100 mTorr). By forming the film at a pressure in this range, microcrystalline silicon can be formed even in the early part of the film formation process. Should the pressure in the chamber be higher than 13.33 Pa, the vapor phase reaction of the silane gas (SiH₄) would be intense so that particles are generated, disadvantageously resulting in formation of amorphous silicon. Should the pressure in the chamber be lower than 0.1333 Pa, the vacuum would be excessively high, resulting in larger plasma damage. This would inhibit crystallization so that only amorphous silicon is disadvantageously formed.

Before the formation of the microcrystalline silicon film 14′, a hydrogen plasma treatment may be performed on the underlying silicon nitride film at a pressure of 1.333 Pa (10 mTorr) for 30 seconds. The thickness of the microcrystalline silicon film 14′ may be 50 nm. The thickness of the silicon nitride film 19′ may be 150 nm. Performing the hydrogen plasma treatment enables the microcrystalline silicon film 14′ to be stably formed even in the early part of the film formation process.

Then, referring to FIG. 3(c), the silicon nitride film 19′ is patterned by self-aligning photolithography in which back exposure is performed via a gate line, whereby the channel protecting layer 19 which functions as an etching stopper layer is formed. Thereafter, the microcrystalline silicon film 14′ is also etched using the same resist pattern so as to form the microcrystalline silicon layer 14. Here, the upper surface and the lower surface of the microcrystalline silicon layer 14 are in contact with the channel protecting layer 19 and the gate insulating film 13, respectively, with only the end surfaces 14c being exposed. The etching of the silicon nitride film 19′ is performed using a mixture gas of carbon tetrafluoride (CF₄) and oxygen (O₂). The etching of the microcrystalline silicon film 14′ is performed using a chlorine (Cl₂) gas,

Then, referring to FIG. 3(d), an n⁺ silicon film 20 which is an impurity layer that contains phosphorus as an impurity is formed by plasma CVD, In this step, the n⁺ silicon film 20 is formed so as to be in contact with the microcrystalline silicon layer 14 only at the end surfaces 14c without being in contact with any of the upper and lower surfaces thereof.

Note that, this step, the impurity doping is not performed after the formation of the silicon film but before the film formation. Specifically, the impurity-doped n⁺ silicon film 20 is formed. Immediately before the start of the formation of the n⁺ silicon film 20, a plasma treatment is performed using a gas which contains phosphine (PH₃) such that the microcrystalline silicon layer 14 is doped with impurities. Immediately after the formation of the n⁺ silicon film 20, the n⁺ silicon film 20 is thermally treated at a temperature not less than 250° C. and not more than 320° C.

With the plasma treatment performed using a gas which contains phosphine (PH₃), the impurities are diffused near the end surfaces 14c of the microcrystalline silicon layer 14. Therefore, an excellent junction is formed between the microcrystalline silicon layer 14 and the n⁺ silicon film 20 so that a high on-current can be achieved. Further, by performing the above-described thermal treatment, the state of junction between these layers can be further improved. Should the thermal treatment be performed at a temperature higher than 320° C., hydrogen would be eliminated from the microcrystalline silicon so that an increased number of defects are formed in the film, resulting in degraded semiconductor characteristics. Should the thermal treatment be performed at a temperature not more than 250° C., the above-described excellent state of junction would not be achieved.

The n⁺ silicon film 20 may be composed of microcrystalline silicon or may be composed of amorphous silicon. The n⁺ silicon film 20 may have a layered structure composed of a high-resistance amorphous n⁺ silicon film (20 nm thick) and a low-resistance microcrystalline n⁺ silicon film (40 nm thick) overlying the high-resistance film. With this layered structure, the current density at the drain end is decreased, so that decrease in the off-current and increase in the on-current are possible. In this case, the sheet resistance of the amorphous n⁺ silicon film may preferably be not less than 5×10⁷ Ω/cm² and not more than 5×10⁸ Ω/cm², and the sheet resistance of the microcrystalline n⁺ silicon film may preferably be not less than 5×10⁴ Ω/cm² and not more than 1×10⁶ Ω/cm².

Thereafter, a molybdenum (Mo) film 21 is formed by sputtering over the n⁺ silicon film 20. The thickness of the molybdenum film 21 may be 200 nm.

Then, referring to FIG. 3(e), the molybdenum film 21 is photolithographically patterned to form the source electrode 17 and the drain electrode 18. The etching employed herein may be wet etching, so that only the molybdenum film 21 can be selectively etched. The etchant used may be an SLA etchant (phosphoric acid+acetic acid).

Note that the metal which constitutes the source electrode 17 and the drain electrode 18 is not necessarily limited to molybdenum. Each of these electrodes may be a single layer formed of a simple metal, such as aluminum (Al), indium tin oxide (ITO), tungsten (W), copper (Cu), chromium (Cr), tantalum (Ta), titanium (Ti), etc., or a material composed of such a simple metal and nitrogen, oxygen, or any other metals. Alternatively, some of these metal materials may be used in combination to form a layered structure.

Then, the photoresist used for the etching of the molybdenum film 21 is used as it is for dry etching of the n⁺ silicon film 20 such that the contact layers 15 and 16 are formed so as to be separated from each other. In this way, the molybdenum film 21 and the n⁺ silicon film 20 can be etched using the same resist pattern, and therefore, formation of the contact layers 15 and 16, the source electrode 17, and the drain electrode 18 can be efficiently accomplished through a single process, without an additional patterning step.

In this etching step, the channel protecting layer 19 which serves as the etching stopper layer prevents the microcrystalline silicon layer 14 from being damaged by dry etching, and thus, there is no concern about deterioration in the on-current characteristic. Further, the microcrystalline silicon layer 14 can be formed to have a smaller thickness, so that the off-current can be decreased. Thus, by employing the above-described etching processes for the molybdenum film 21 and the n⁺ silicon film 20, a thin film transistor which is excellent in terms of both the on-current characteristic and the off-current characteristic can be efficiently fabricated.

Then, referring to FIG. 3(f), a silicon nitride layer 25, which is a passivation film, is formed by plasma CVD so as to cover the source electrode 17, the drain electrode 18, and the channel protecting layer 19, and then, a planarization layer (JAS film) 26 is formed over the resultant silicon nitride layer 25. Thereafter, a contact hole is formed in the planarization layer 26 and the silicon nitride layer 25, and an ITO (Indium Tin Oxide) film is formed by sputtering so as to be in contact with the drain electrode 18 via the contact hole. In the final step, the ITO film is reshaped to form a transparent electrode 27, whereby fabrication of a switching element that is to be included in each pixel of the display device is completed.

### Embodiment 2

Next, a thin film transistor 50 of embodiment 2 of the present invention is described.

FIG. 4 is a cross-sectional view which schematically shows a structure of the thin film transistor 50. As shown in FIG. 4, the thin film transistor 50 is a staggered TFT which has a top gate structure. The thin film transistor 50 includes a contact layer (first contact layer) 55 and a contact layer (second contact layer) 56 which are provided on a glass substrate 51, silicon oxide layers (insulating layers) 61 and 62 which are provided on the contact layers 55 and 56, respectively, a microcrystalline silicon layer 54 which serves as an active layer and which is provided on the glass substrate 51 so as to cover part of the silicon oxide layers 61 and 62, a gate insulating layer 53 which is provided over the microcrystalline silicon layer 54, and a gate electrode 52, a source electrode 57 and a drain electrode 58 which are provided on the gate insulating layer 53.

The microcrystalline silicon layer 54 has an upper surface 54a and a lower surface 54b which are substantially parallel to a substrate surface, and end surfaces (side surfaces) 54c which extend between the upper surface 54a and the lower surface 54b. The contact layer 55 and the contact layer 56 are in contact with the microcrystalline silicon layer 54 only at the end surfaces 54c without being in contact with any of the upper surface 54a and the lower surface 54b.

The contact layers 55 and 56 are made of impurity-doped n⁺ type silicon (n⁺-Si). When seen in a direction perpendicular the substrate surface, part of the microcrystalline silicon layer 54 is provided on the silicon oxide layers 61 and 62. Thus, the part of the microcrystalline silicon layer 54 extends over the contact layers 55 and 56 with the silicon oxide layers 61 and 62 interposed therebetween.

The microcrystalline silicon layer 54 is made of the same material as that of the microcrystalline silicon layer 14 of embodiment 1. Specifically, the microcrystalline silicon layer 54 includes amorphous silicon and columnar crystals grown vertically to the substrate surface. The thin film transistor 50 has a coplanar structure in which the contact layers 55 and 56 are joined to the microcrystalline silicon layer 54 only at the end surfaces 54c of the microcrystalline silicon layer 54. Thus, the thin film transistor 50 can also provide the same effects as those described in embodiment 1.

Fabrication of the thin film transistor 50 does not require an additional impurity introduction process because the contact layers 55 and 56 are obtained by directly forming a silicon film which contains impurities. Therefore, the thin film transistor 50 of embodiment 2 is of high fabrication efficiency and is suitable to, for example, a device which has a large display surface, such as large-size liquid crystal display devices. The contact layers 55 and 56 and the silicon oxide films 61 and 62 are reshaped using a single mask. This also improves the fabrication efficiency.

Large part of the current flowing between the source electrode 57 and the drain electrode 58 passes through the microcrystalline silicon layer 54. Therefore, the mobility in the thin film transistor 50 is higher than that in an amorphous silicon TFT. In the thin film transistor 50, the off-current rising is prevented for the same reasons as those described in embodiment 1 with reference to FIG. 2, so that the leakage current is also prevented, whereas the microcrystalline silicon TFT 120 shown in FIG. 8 has a problem that a rising of the current would occur as in the microcrystalline silicon TFT 100 of FIG. 6 and a large leakage current flows.

The materials of the microcrystalline silicon layer 54, the contact layer 55, and the contact layer 56 and the state of junction between these layers are the same as those of the microcrystalline silicon 14 and the contact layers 15 and 16 of embodiment 1. Therefore, the configuration of these layers of embodiment 2 provides the same effects as those described in embodiment 1. Thus, embodiment 2 is also capable of achieving a high on-current value while decreasing the off-current.

Next, a method for fabricating the thin film transistor 50 of embodiment 2 is described with reference to FIG. 5.

FIG. 5 is a cross-sectional view which illustrates a method for fabricating the thin film transistor 50. First, the steps of forming a layered structure which is composed of the contact layers 55 and 56 and the silicon oxide layers 61 and 62 are described with reference to FIG. 5(a).

First, an n⁺ silicon film, which is an impurity layer that contains phosphorus as an impurity, is formed on the glass substrate 51 by plasma CVD. In this step, the impurity doping is not performed after formation of the silicon film, but simultaneously with formation of the silicon film so that an impurity-doped n⁺ silicon film is formed.

This n⁺ silicon film may be composed of microcrystalline silicon or may be composed of amorphous silicon. The n⁺ silicon film may have a layered structure composed of a high-resistance amorphous n⁺ silicon film (20 nm thick) and a low-resistance microcrystalline n⁺ silicon film (40 nm thick) overlying the high-resistance film. With this layered structure, the current density at the drain end is decreased, so that decrease in the off-current and increase in the on-current are possible. In this case, the sheet resistance of the amorphous n⁺ silicon film is preferably not less than 5×10⁷ Ω/cm² and not more than 5×10⁸ Ω/cm², and the sheet resistance of the microcrystalline n⁺ silicon film is preferably not less than 5×10⁴ Ω/cm² and not more than 1×10⁶ Ω/cm².

Then, a silicon oxide film is formed on the n⁺ silicon film by plasma CVD. The resultant layered structure is then subjected to a thermal treatment at about 670° C. for about 20 minutes. This treatment can decrease the resistance of the n⁺ silicon film to about 500 Ω/cm².

Thereafter, the both films are patterned to form a layered structure consisting of the contact layers 55 and 56 and the silicon oxide layers (insulating layers) 61 and 62 as shown in FIG. 5(a). The etching used herein may be dry etching with an etching gas containing oxygen. During progress of the etching, a photoresist is gradually moved away from the substrate such that a cross section of the layered structure is tapered at 45° relative to the substrate.

Then, a microcrystalline silicon film is formed over the above-described layered structure. The microcrystalline silicon film may be formed by high-density plasma CVD, (ICP-CVD, surface wave CVD, or ECR-CVD). The microcrystalline silicon film may be formed using a mixture gas containing silane (SiH₄) and hydrogen (H₂) in the ratio of 1:20 in a chamber where the pressure is 1.333 Pa (=10 mTorr) and the substrate temperature is 300° C.

Before the formation of the microcrystalline silicon film, a hydrogen plasma treatment may be performed on the underlying layer at a pressure of 0.667 Pa (5 mTorr) for 30 seconds. The thickness of the microcrystalline silicon film may be 60 nm. Performing the hydrogen plasma treatment enables the microcrystalline silicon film to be stably formed even in the early part of the film formation process.

Thereafter, the microcrystalline silicon film is photolithographically patterned to form the microcrystalline silicon layer 54, which serves as an active layer, as shown in FIG. 5(b). In this step, the microcrystalline silicon layer 54 is formed such that the contact layers 55 and 56 are in contact with the microcrystalline silicon layer 54 only at the end surfaces 54c without being in contact with any of the upper and lower surfaces thereof. When seen in a direction perpendicular the substrate surface, part of the microcrystalline silicon layer 54 extends over the contact layers 55 and 56 with the silicon oxide layers 61 and 62 interposed therebetween.

The etching used for the microcrystalline silicon film is dry etching, such that the microcrystalline silicon film can be reshaped so as to have a finer geometry. The etching gas used may be a chlorine (Cl₂) gas such that erosion of the silicon oxide layers 61 and 62 can be readily prevented. The etching may be continued while being monitored by an end point detector (EPD) till the silicon oxide layers 61 and 62 are reached.

Then, referring to FIG. 5(c), a gate insulating layer 53 is formed over the microcrystalline silicon layer 54. The thickness of the gate insulating layer 53 may be 250 nm. The material used herein for the gate insulating layer 53 is a silicon oxide but may be a silicon nitride.

Then, referring to FIG. 5(d), photolithographic patterning is performed to form a contact hole in the gate insulating layer 53. Thereafter, three layers including a Ti (titanium) film, an Al (aluminum) film, and a Ti film are formed by sputtering. The thicknesses of these films may be 50 nm, 100 nm, and 50 nm, respectively. Thereafter, these three layers are simultaneously patterned to form a gate electrode 52, a source electrode 57, and a drain electrode 58.

Then, referring to FIG. 5(e), a silicon nitride layer 65, which is a passivation layer, is formed by plasma CVD so as to cover the gate electrode 52, the source electrode 57, and the drain electrode 58, and then, a planarization layer (JAS film) 66 is formed over the resultant silicon nitride layer 65. Thereafter, a contact hole is formed in the planarization layer 66 and the silicon nitride layer 65, and an ITO film is formed by sputtering so as to be in contact with the drain electrode 58 via the contact hole. In the final step, the ITO film is reshaped to form a transparent electrode 67, whereby fabrication of a switching element that is to be included in each pixel of the display device is completed.

### INDUSTRIAL APPLICABILITY

The present invention is suitable to display devices which include an active matrix substrate that has thin film transistors, such as liquid crystal display devices, organic electroluminescence (EL) display devices, inorganic electroluminescence display devices, etc., imaging devices, such as flat-panel X-ray imaging sensor devices, etc., and image capturing devices, such as contact image scanners, fingerprint readers, etc.

1. A thin film transistor which has a semiconductor layer containing a microcrystalline silicon, comprising:
a gate electrode;
a microcrystalline silicon layer containing a microcrystalline silicon, the microcrystalline silicon layer having an upper surface and a lower surface which are parallel to a substrate surface and an end surface which extends between the upper surface and the lower surface;
first and second contact layers containing impurities;
a source electrode which is in contact with the first contact layer; and
a drain electrode which is in contact with the second contact layer,
wherein at least one of the first and second contact layers is in contact with the microcrystalline silicon layer only at the end surface without being in contact with any of the upper surface and the lower surface.

2. The thin film transistor of claim 1, wherein at least part of the first and second contact layers extends over the microcrystalline silicon layer when seen in a direction perpendicular to the substrate surface.

3. The thin film transistor of claim 1, wherein part of the source electrode extends over the first contact layer, or part of the drain electrode extends over the second contact layer, when seen in a direction perpendicular to the substrate surface.

4. The thin film transistor of claim 1, wherein
the thin film transistor is a bottom gate type thin film transistor,
the first contact layer and a gate insulation layer are provided between the source electrode and the gate electrode, and
the second contact layer and a gate insulation layer are provided between the drain electrode and the gate electrode.

5. The thin film transistor of claim 1, wherein part of the microcrystalline silicon layer extends over the first contact layer or the second contact layer when seen in a direction perpendicular to the substrate surface.

6. The thin film transistor of claim 5, wherein
the thin film transistor is a top gate type thin film transistor, and
the part of the microcrystalline silicon layer extends over the first contact layer or the second contact layer with an insulating layer interposed therebetween.

7. The thin film transistor of claim 1, wherein the microcrystalline silicon layer includes a columnar crystal grown vertically to the substrate surface.

8. The thin film transistor of claim 7, wherein a cross section of the columnar crystal which is parallel to the substrate surface has a diameter not less than 5 nm and not more than 30 nm.

9. The thin film transistor of claim 1, wherein a crystallization rate of the microcrystalline silicon layer is 70% or more.

10. The thin film transistor of claim 1, wherein the microcrystalline silicon layer includes a void.

11. The thin film transistor of claim 1, wherein an infrared absorption spectrum of the microcrystalline silicon layer has a peak in a wave number range of not less than 2050 cm⁻¹ and not more than 2150 cm⁻¹.

12. The thin film transistor of claim 1, wherein each of the first and second contact layers includes an amorphous silicon layer which contains impurities and a microcrystalline silicon layer which contains impurities.

13. A display device comprising the thin film transistor of claim 1.

14. A method for fabricating a thin film transistor which has a semiconductor layer containing a microcrystalline silicon, the method comprising the steps of:
forming a gate electrode;
forming a microcrystalline silicon layer which contains a microcrystalline silicon;
forming first and second contact layers which contain impurities; and
forming a source electrode and a drain electrode so as to be in contact with the first and second contact layers, respectively,
wherein the microcrystalline silicon layer has an upper surface and a lower surface which are parallel to a substrate surface and an end surface which extends between the upper surface and the lower surface, and
at least one of the first and second contact layers and the microcrystalline silicon are formed so as to be in contact with each other only at the end surface of the microcrystalline silicon layer without having a contact at any of the upper surface and the lower surface.

15. The method of claim 14, wherein the step of forming the first and second contact layers includes
forming a layer of a silicon which contains impurities, and
reshaping the layer of the silicon which contains the impurities to form the first and second contact layers.

16. The method of claim 14, wherein
the thin film transistor is a bottom gate type thin film transistor,
the step of forming the gate electrode and the step of forming the microcrystalline silicon layer is performed before the step of forming the first and second contact layers, and
the first and second contact layers, the source electrode, and the drain electrode are formed by reshaping with the use of a single pattern.

17. The method of claim 14, wherein
the thin film transistor is a top gate type thin film transistor,
the step of forming the microcrystalline silicon layer, the step of forming the gate electrode, the step of forming the source electrode and the drain electrode is performed after the step of forming the first and second contact layers, and
the step of forming the first and second contact layers includes
forming a silicon film which contains impurities,
forming an insulating film on the silicon film, and
reshaping the silicon film and the insulating film with the use of a single pattern.

18. The method of claim 15 further comprising, before forming the layer of the silicon which contains the impurities, doping the microcrystalline silicon layer with impurities using a gas which contains phosphine (PH₃).

19. The method of claim 15, further comprising, after forming the layer of the silicon which contains the impurities, thermally treating the layer of the silicon which contains the impurities at a temperature not less than 250° C. and not more than 320° C.

20. The method of claim 14, wherein the step of forming the microcrystalline silicon layer includes
forming a microcrystalline silicon film by high-density plasma CVD, and
reshaping the microcrystalline silicon film to form the microcrystalline silicon layer.

21. The method of claim 20, wherein the step of forming the microcrystalline silicon film includes forming the microcrystalline silicon layer at a pressure not less than 0.133 Pa (pascal) and not more than 13.3 Pa.

22. The method of claim 20, wherein the microcrystalline silicon film is formed on a silicon nitride film after a hydrogen plasma treatment is performed on the silicon nitride film.
